(19) United States
(12) Patent Application Publication
(10) Pub. No.: US 2023/0030628 A1
(43) Pub. Date: Feb. 2, 2023

(54) ELECTRONIC DEVICE WITH LIQUID COOLING MECHANISM

(71) Applicant: UNIWILL TECHNOLOGY INC., Taipei (TW)

(72) Inventors: Chih-Hsien CHEN, Taipei (TW); Yu-Cheng SHIH, Taipei (TW); Pon-Chung CHIEN, Taipei (TW)

(21) Appl. No.: 17/746,679

(22) Filed: May 17, 2022

(30) Foreign Application Priority Data
Jul. 30, 2021 (TW) 110209028

(51) Int. Cl. H05K 7/20; G06F 1/20

(52) U.S. Cl. CPC H05K 7/20327; G06F 1/20; H05K 7/20136; H05K 7/20336

(57) ABSTRACT

An electronic device (10) with a liquid cooling mechanism includes an electronic device body (1), a heat dissipation module (2) and a liquid cooling module (3). The electronic device body (1) includes a housing (11) and at least one heat generating element (12) installed in the housing (11). The heat dissipation module (2) is contained in the housing (11) and attached to the heat generating element (12). The liquid cooling module (3) includes a liquid cooling pipe (31) contained in the housing (11) and attached to the heat dissipation module (2), and two ends of the liquid cooling pipe (31) have two interface portions (311) exposed from the housing (11). In this way, the liquid cooling pipe (31) is used for water cooling to achieve a desirable cooling efficiency for the electronic device (10).

### BACKGROUND OF THE DISCLOSURE

### Technical Field

The technical field relates to a liquid cooling structure, and more particularly relates to an electronic device with a liquid cooling mechanism.

### Description of Related Art

Nowadays, electronic devices such as notebook computers, tablet PCs, etc. have more and more functions, so that the computing units in the electronic device become increasingly greater in number and more effective in computation, and these units generate a large amount of heat. Therefore, a heat dissipation structure is introduced and installed inside the electronic device, and provided for dissipating the generated heat to the exterior of the electronic device.

However, the related-art heat dissipation structure mainly includes components such as heat pipes, heat dissipation fins and fans. Since the overall appearance of the electronic devices is emphasized on a thin, lightweight, and compact design, leading to lighter, smaller, and fewer heat pipes, heat dissipation fins and fans, therefore the heat dissipation capacity is insufficient to effectively lower the temperature of the computing units, and the performance of the electronic devices is limited.

In view of the aforementioned drawbacks, the discloser proposed this disclosure based on his expert knowledge and elaborated researches to overcome the drawbacks of the related art.

### SUMMARY OF THE DISCLOSURE

This disclosure is directed to an electronic device with a liquid cooling mechanism, which uses a liquid cooling pipe for water cooling, and achieves a desirable heat dissipation efficiency of the electronic device.

In an embodiment, this disclosure provides an electronic device with a liquid cooling mechanism, including: an electronic device body having a housing and at least one heat generating element installed in the housing; a heat dissipation module contained in the housing and attached to the at least one heat generating element; and a liquid cooling module having a liquid cooling pipe contained in the housing and attached to the heat dissipation module, and two ends of the liquid cooling pipe are exposed from two interface portions of the housing.

Based on the above, the heat dissipation module includes a plurality of heat pipes, a liquid cooling pipe attached to the plurality of heat pipes, such that a working fluid inside the liquid cooling pipe may water-cool the heat pipes quickly to improve the heat dissipation efficiency of the electronic device significantly.

Based on the above, only the liquid cooling pipe is contained in the housing, and other components of the liquid cooling module are connected externally to facilitate maintaining the thin, lightweight, and compact design of the electronic device, and thus the electronic device has the advantage of reducing its volume.

### BRIEF DESCRIPTION OF THE DRAWINGS

FIG. 1 is a perspective view of an electronic device of this disclosure;

FIG. 2 is a cross-sectional view of an electronic device of this disclosure;

FIG. 3 is a perspective view of a heat dissipation module and a liquid cooling module of this disclosure;

FIG. 4 is a perspective exploded view of a heat dissipation module and a liquid cooling module of this disclosure;

FIG. 5 is another perspective exploded view of a heat dissipation module and a liquid cooling module of this disclosure;

FIG. 6 is a schematic view showing a using status of a liquid cooling pipe of this disclosure and

FIG. 7 is another cross-sectional view of an electronic device of this disclosure.

### DETAILED DESCRIPTION

The technical contents of this disclosure will become apparent with the detailed description of embodiments accompanied with the illustration of related drawings as follows. It is intended that the embodiments and drawings disclosed herein are to be considered illustrative rather than restrictive.

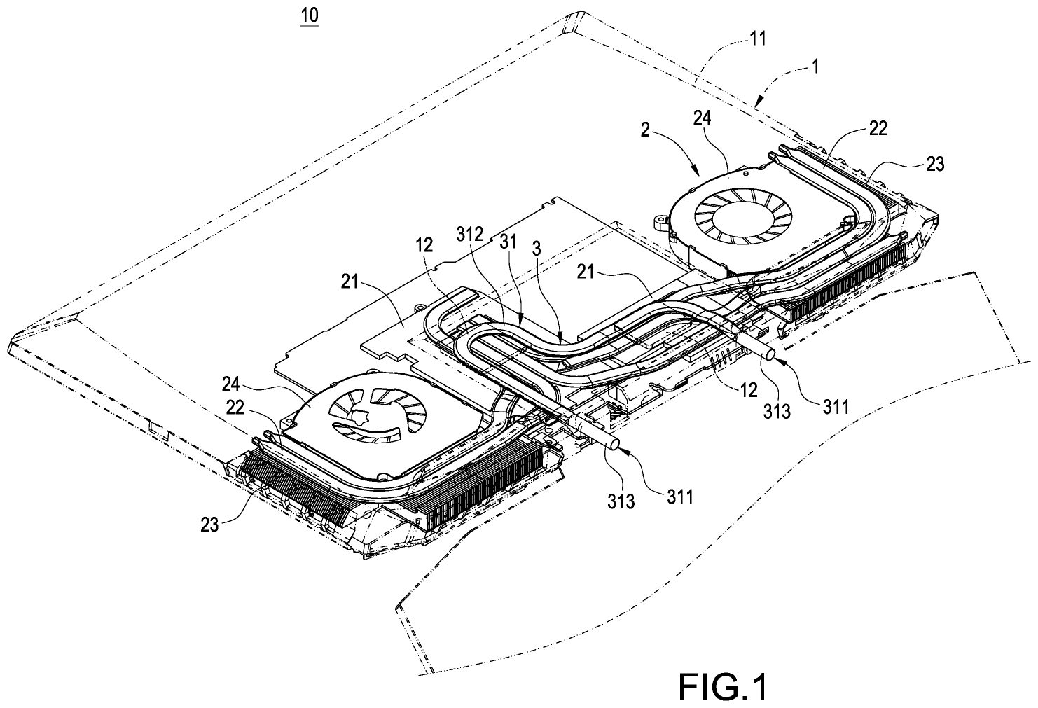

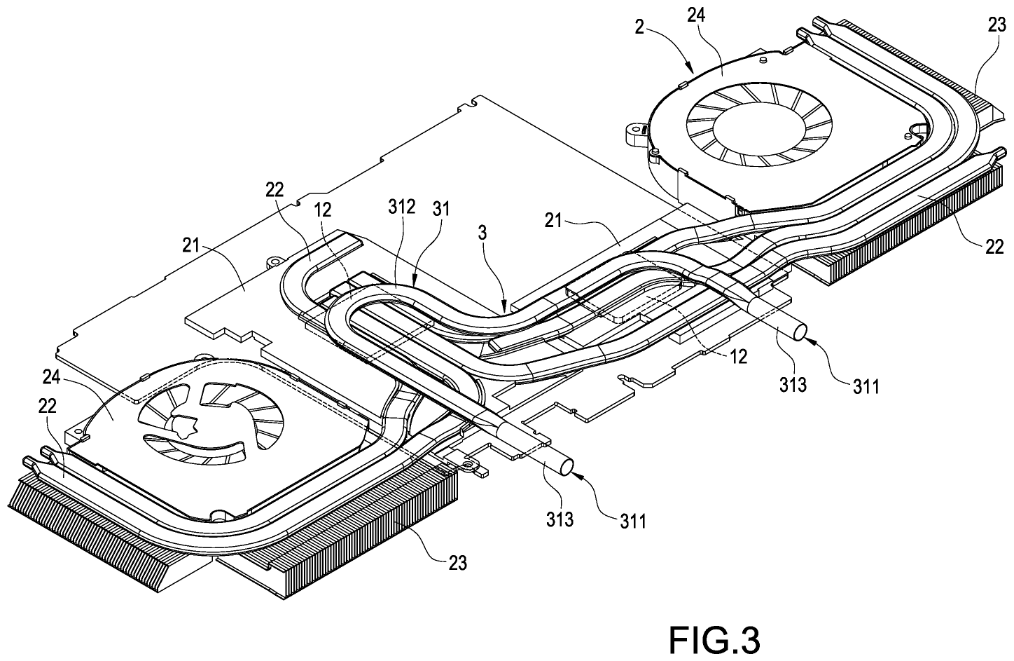

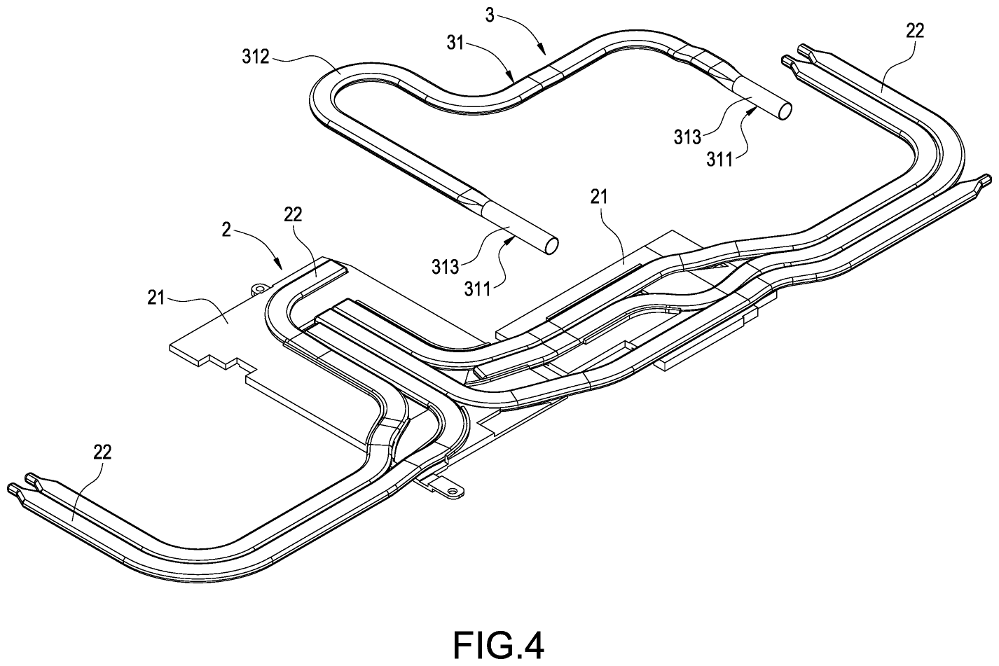

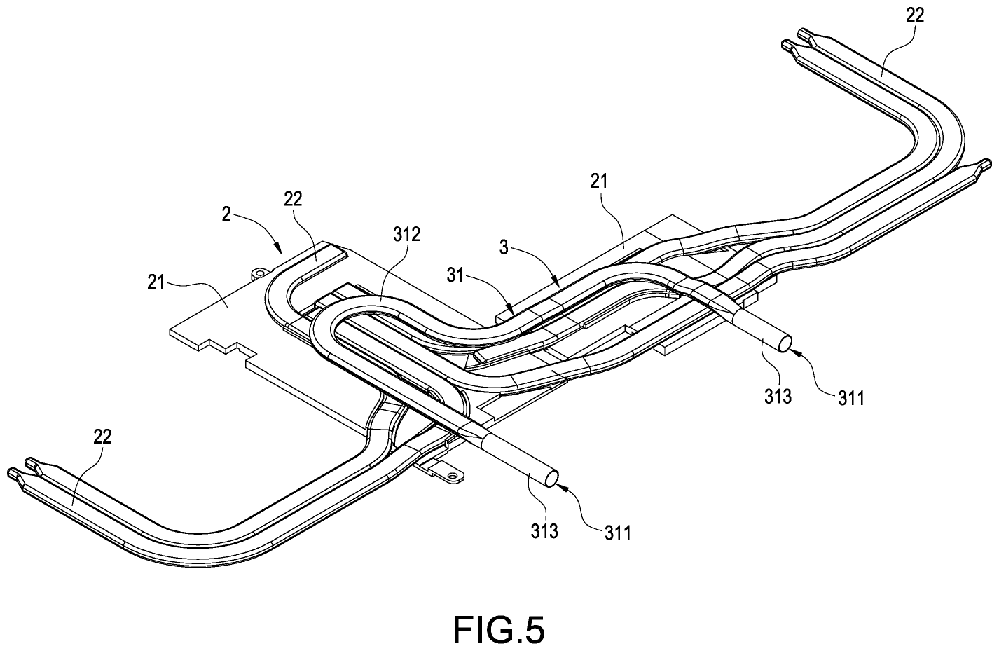

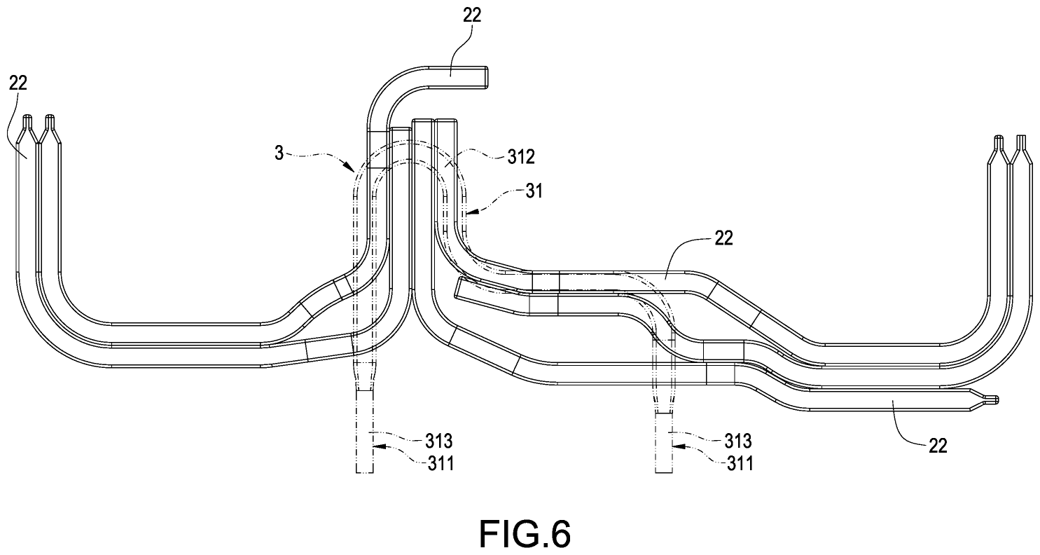

With reference to FIG. 1 to FIG. 6 for an electronic device with a liquid cooling mechanism of this disclosure, the electronic device 10 includes an electronic device body 1, a heat dissipation module 2 and a liquid cooling module 3.

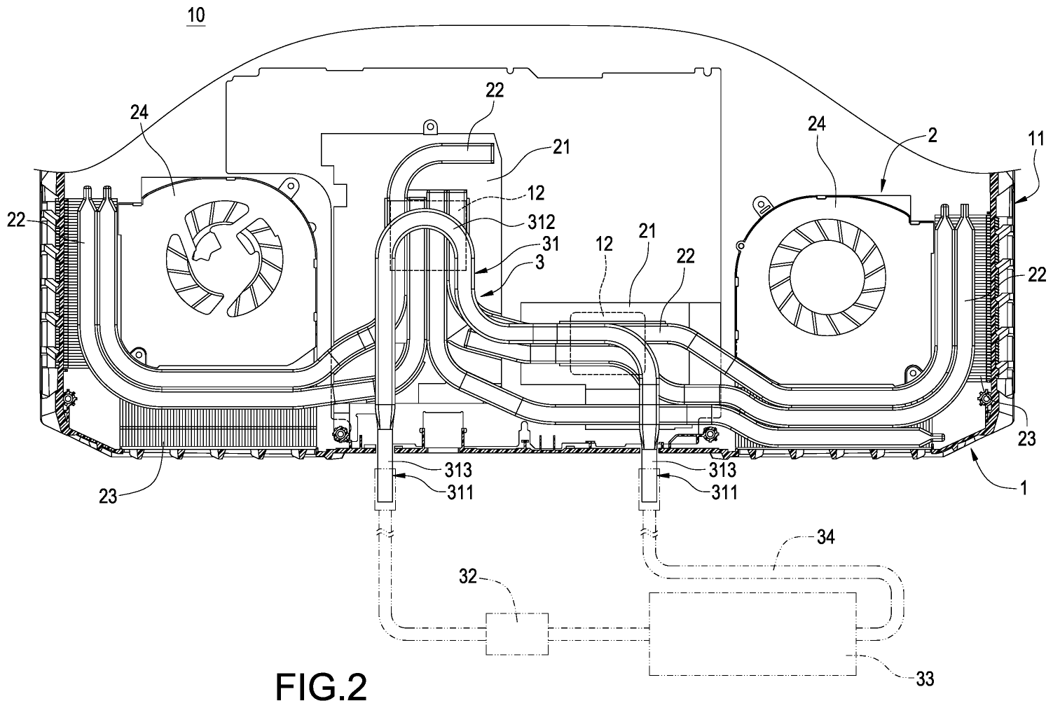

In FIG. 1 and FIG. 2, the electronic device body 1 includes a housing 11 and one or more heat generating elements 12 installed in the housing 11. In this embodiment, there are a multiple of heat generating elements 12, but this disclosure is not limited to such arrangement.

In FIG. 1 to FIG. 6, the heat dissipation module 2 is contained in the housing 11 and attached to the heat generating element 12, and the heat dissipation module 2 includes one or more heat conduction blocks 21, a plurality of heat pipes 22, one or more cooling fin modules 23 and one or more fans 24.

In details, the heat conduction block 21, cooling fin module 23 and fan 24 of this embodiment come with a multiple quantity, but this disclosure is not limited to such arrangement. Each heat conduction block 21 is attached to the top of each heat generating element 12, and the plurality of heat pipes 22 is fixed to the top of the plurality of heat conduction block 21, and the cooling fin module 23 is connected to the ends of the plurality of heat pipes 22, and each fan 24 and each cooling fin module 23 are stacked on one another.

In FIG. 1 to FIG. 6, the liquid cooling module 3 includes a liquid cooling pipe 31 contained in the housing 11 and attached to the plurality of heat pipes 22 of the heat dissipation module 2, and two ends of the liquid cooling pipe 31 have two interface portions 311 exposed from the housing 11.

Further, the liquid cooling pipe 31 of this embodiment is bent along the disposing positions of the plurality of heat pipes 22 to form one or more U-shaped sections, so that the liquid cooling pipe 31 is attached to each heat pipe 22 securely, and the liquid cooling pipe 31 of this embodiment is in a flat shape that is tightly attached to the heat pipe 22, but this disclosure is not limited to the flat shape only.

In addition, the liquid cooling module 3 further includes a pump 32, a water cooler 33 and a delivery pipe 34, which are installed outside the housing 11, and two ends of the delivery pipe 34 are detachably connected to the two interface portions 311 and serially connected with the pump 32 and the water cooler 33, and the pump 32 guides a working fluid to circulate between the liquid cooling pipe 31 and the water cooler 33, such that the working fluid absorbs heat at the liquid cooling pipe 31 and discharges heat at the water cooler 33.

In addition, the liquid cooling pipe 31 is a hollow pipe 312, and the two interface portions 311 are formed at two ends of the hollow pipe 312 and protruded from two open ends 313 of the housing 11, and two ends of the delivery pipe 34 detachably sheathe the two open ends 313, such that the delivery pipe 34 and the liquid cooling pipe 31 are communicated to each other. The hollow pipe 312 is made of metal, ceramic, or other materials with desirable thermal conductivity.

In FIG. 1 to FIG. 6, the electronic device 10 of this disclosure uses the heat conduction block 21, heat pipe 22, cooling fin module 23 and fan 24 to dissipate the heat of the heat generating element 12 to the outside of the housing 11, while the liquid cooling pipe 31 is attached to the plurality of heat pipes 22, such that the working fluid in the liquid cooling pipe 31 may water-cool the heat pipe 22 quickly to improve the heat dissipation efficiency of the electronic device 10.

In this disclosure, only the liquid cooling pipe 31 is contained in the housing 11, and other components of the liquid cooling module (such as the pump 32, water cooler 33, delivery pipe 34, etc.) are connected externally to facilitate maintaining the thin, lightweight, and compact design of the electronic device 10, so that the electronic device 10 has the advantage of reducing its size.

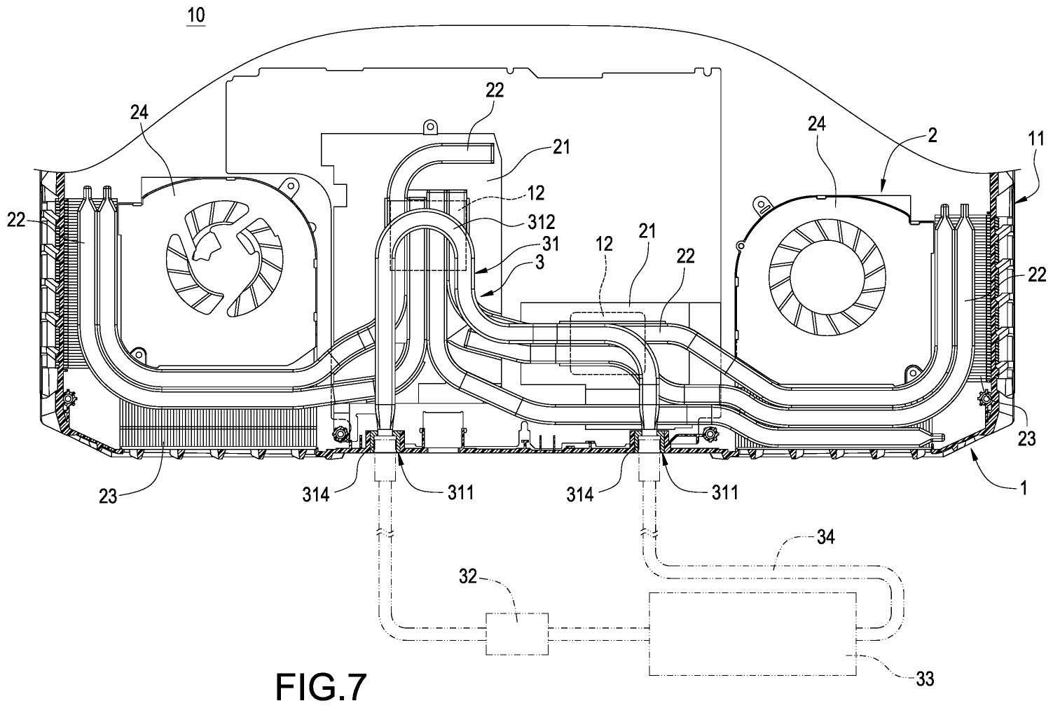

With reference to FIG. 7 for an electronic device 10 in accordance with another embodiment of this disclosure, this embodiment is substantially the same as the embodiment as shown in FIG. 1 to FIG. 6, except that the structure of the interface portion 311 is different.

In details, the two interface portions 311 of this embodiment are installed at two ends of the hollow pipe 312 and protruded from the housing 11 within approximately 5 mm, or aligned evenly with or concavely formed at two pipe joints 314 of the housing 11, and two ends of the delivery pipe 34 are detachably connected to the two pipe joints 314, such that the delivery pipe 34 and the liquid cooling pipe 31 communicate to each other, and the interface portion 311 is not protruded from the housing 11, so as to improve the aesthetic appearance and the safety of use of the electronic device 10.

The pipe joint 314 is a tubular sleeve made of rubber, silicone, or other water-resistant material, which may avoid the liquid leakage problem at the connection between the delivery pipe 34 and the liquid cooling pipe 31.

In summation of the description above, the electronic device with a liquid cooling mechanism of this disclosure may surely achieve the expected objectives and overcome the drawbacks of the related art. While this disclosure has been described by means of specific embodiments, numerous modifications and variations could be made thereto by those skilled in the art without departing from the scope and spirit of this disclosure set forth in the claims.

What is claimed is:

1. An electronic device, comprising:
an electronic device body (1), comprising a housing (11) and at least one heat generating element (12) installed in the housing (11);
a heat dissipation module (2), contained in the housing (11) and attached to the at least one heat generating element (12); and
a liquid cooling module (3), comprising a liquid cooling pipe (31) contained in the housing (11) and attached to the heat dissipation module (2), and two interface portions (311) disposed on two ends of the liquid cooling pipe (31) and exposed from the housing (11).

2. The electronic device according to claim 1, wherein the heat dissipation module (2) comprises at least one heat conduction block (21) attached to the at least one heat generating element (12) and a plurality of heat pipes (22) fixed to the at least one heat conduction block (21), and the liquid cooling pipe (31) is attached to the plurality of heat pipes (22).

3. The electronic device according to claim 2, wherein the liquid cooling pipe (31) is a hollow pipe (312), and the two interface portions (311) are two open ends (313) disposed on two ends of the hollow pipe (312) respectively and protruded from the housing (11).

4. The electronic device according to claim 2, wherein the liquid cooling pipe (31) is a hollow pipe (312), and the two interface portions (311) are two pipe joints (314) installed to two ends of the hollow pipe (312) respectively.

5. The electronic device according to claim 2, wherein the liquid cooling module (3) further comprises a pump (32), a water cooler (33) and a delivery pipe (34), and the pump (32), the water cooler (33) and the delivery pipe (34) are installed to exterior of the housing (11), and two ends of the delivery pipe (34) are detachably coupled to the two interface portions (311) and connected in series with the pump (32) and the water cooler (33).

6. The electronic device according to claim 2, wherein the heat dissipation module (2) further comprises at least one cooling fin module (23) coupled to an end of the plurality of heat pipes (22) and at least one fan (24) stacked on the at least one cooling fin module (23).
